(19) United States
(12) Patent Application Publication
(10) Pub. No.: US 2008/0093594 A1
(43) Pub. Date: Apr. 24, 2008

(54) ORGANIC SEMICONDUCTOR DEVICE, MANUFACTURING METHOD OF THE SAME, ORGANIC TRANSISTOR ARRAY, AND DISPLAY

(76) Inventors: Hiroyuki HONDA, Tokyo (JP); Hironori KOBAYASHI, Tokyo (JP); Masanao MATSUOKA, Tokyo (JP); Mitsutaka NAGAE, Tokyo (JP)

Correspondence Address: LADAS & PARRY LLP, 224 SOUTH MICHIGAN AVENUE, SUITE 1600, CHICAGO, IL, 60604, US

(21) Appl. No.: 11/855,308

(22) Filed: Sep. 14, 2007

(30) Foreign Application Priority Data
Sep. 29, 2006 (JP) 2006-268609
Mar. 30, 2007 (JP) 2007-091690

(51) Int. Cl. H01L 51/10; H01L 51/48

(52) U.S. Cl. 257/40; 438/99; 257/E51.006

(57) ABSTRACT

The present invention mainly intends to provide an organic semiconductor device having an organic semiconductor transistor reduced in off current. In order to achieve the object, the present invention provides an organic semiconductor device comprising a substrate and an organic semiconductor transistor provided with a gate electrode formed on the substrate, a gate insulation layer formed on the gate electrode, source and drain electrodes which are porous bodies and are formed on the gate insulation layer and an organic semiconductor layer which is made of an organic semiconductor material and formed only between the source and drain electrodes.

### BACKGROUND OF THE INVENTION

1. Field of the Invention

The present invention relates to an organic semiconductor device using an organic semiconductor transistor, a manufacturing method of the organic semiconductor device, an organic transistor array and a display.

2. Description of the Related Art

A semiconductor transistor typified by TFT shows the current trend towards spreading of its applications along with the development of display devices. Such a semiconductor transistor functions as a switching element when the electrodes are connected through a semiconductor material.

Here, as illustrated in FIG. 5, a transistor using the semiconductor material is usually provided with a gate electrode 101, a gate insulating layer 102 insulating the gate electrode 101, a semiconductor layer 103 made of the semiconductor material and a source electrode 104 and a drain electrode 105 formed in such a manner as to be in contact with the semiconductor layer 103. As the transistor, there are a type having a bottom gate structure in which the gate electrode 101 is disposed on the backside of the semiconductor layer 103 (FIG. 5A) and a top gate type in which the gate electrode 101 is disposed on the front side of the semiconductor layer 103 (FIG. 5B) are known.

As the semiconductor material used for the semiconductor transistor, inorganic semiconductor materials such as silicon (Si), gallium arsenic (GaAs) and indium gallium arsenic (InGaAs) are used. Semiconductor transistors using such an inorganic semiconductor are also used for display TFT array substrates of liquid crystal display devices which have been widely spread in recent years. On the other hand, organic semiconductor materials made of organic compounds are known as the semiconductor material.

Transistors using such organic semiconductor materials have an advantage in that they are allowed to be increased in area at a lower cost than those using the inorganic semiconductor materials, they can be formed on a flexible plastic substrate and are also stable against mechanical impact. Therefore, active studies are being made as to technologies assumed to be applied display devices such as flexible displays typified by electronic paper in the next generation.

Here, as mentioned above, semiconductor transistors using the semiconductor material are usually constituted of a gate electrode, a gate insulation layer, a semiconductor layer made of a semiconductor material, a source electrode and a drain electrode, and are made to develop switching functions by changing the amount of charges on the interface of the semiconductor by gate voltage to control drain current. It is necessary that the on-off ratio which is the ratio of the currents when the transistor is on and off is large enough to develop a sufficient switching function. When the on-off ratio is large, a large change in drain current can be obtained by a slight change in gate electrode and therefore, a sufficient switching function can be developed. When the on-off ratio is small on the other hand, a change in drain current is small for a change in gate voltage and it is necessary to apply a large voltage to the gate electrode to develop a switching function.

The on-off ratio has a large influence on the development of a switching function which is the essential function of a transistor as mentioned above. The organic semiconductor transistors have the problem that they have a smaller on-off ratio than inorganic semiconductor transistors.

Examples of the reasons that the on-off ratio becomes small include the case where on-current is small and the case where off-current is high. The problem is posed in the case where the off-current of the organic semiconductor transistor is high among these cases. The organic semiconductor layer constituting the organic semiconductor transistor has a difficulty in fine processing such as the formation of a pattern-wise organic semiconductor layer made of an organic semiconductor material and therefore has a larger area than the gate electrode, with the result that current flows round through other routes even when the device is turned off, leading to an increase in off-current.

The publication of Japanese Patent Application Laid-Open No. 2000-269504, in turn, discloses a method in which an insulation layer is formed on a source/drain electrode and then, an organic semiconductor layer is formed of an organic semiconductor material by using a vapor deposition method so as to be in contact with the source/drain electrode. However, this method has the problem that it is inferior in productivity to printing methods, such as a screen printing method and ink jet method, in which the organic semiconductor material put into a coating liquid state is applied.

Also, in conventional methods used to carry out patterning of an organic semiconductor layer, a dividing wall is formed using a resin or the like to form a pattern within the area enclosed by the dividing wall by an ink jet method or the like. In this case, because the dividing wall-formation step of forming such a dividing wall is necessary as a separate step, this method poses the problem concerning inferior productivity.

### SUMMARY OF THE INVENTION

The present invention has been made in view of the problems, and it is a main object of the present invention to provide an organic semiconductor device having an organic semiconductor transistor reduced in off current.

In order to achieve the object, the present invention provides an organic semiconductor device comprising a substrate and an organic semiconductor transistor provided with a gate electrode formed on the substrate, a gate insulation layer formed on the gate electrode, source and drain electrodes which are porous bodies and are formed on the gate insulation layer and an organic semiconductor layer which is made of an organic semiconductor material and formed only between the source and drain electrodes.

The present invention also provides an organic semiconductor device comprising a substrate and an organic semiconductor transistor provided with source and drain electrodes which are porous bodies and are formed on the substrate, an organic semiconductor layer which is made of an organic semiconductor material and formed only between the source and drain electrodes, a gate insulation layer formed on the organic semiconductor layer and a gate electrode formed on the gate insulation layer.

According to the present invention, the amount of drain current when the device is switched off, that is, off-current can be made to be low because the organic semiconductor layer is formed only between the source electrode and drain electrode. Also, according to the present invention, the source electrode and drain electrode are respectively made of a porous body. Therefore, when, for example, the organic semiconductor device of the present invention is produced and the organic semiconductor layer is formed by an additive method, the source and drain electrodes can absorb the organic semiconductor material and support the organic semiconductor material stably between them, which makes it easy to form the organic semiconductor layer stably.

Moreover, since the organic semiconductor material can be held stably between the electrodes, the height of the source and drain electrodes may be reduced, whereby the source and drain electrodes can be easily formed. Also, the surface of the organic semiconductor device of the present invention can be easily flattened, and therefore, a passivation layer and a counter electrode can be easily formed.

This is the reason why an organic semiconductor device superior in on-off ratio can be obtained according to the present invention.

In the present invention, the organic semiconductor material is preferably contained in the pores formed in the source and drain electrodes. This is because this substantially improves the contact area between the organic semiconductor layer and the source electrode or drain electrode, and therefore, the performance of the organic semiconductor transistor of the invention can be improved. It is also because when the organic semiconductor layer is formed such that the organic semiconductor material is included in the source and drain electrodes in this manner, and it is therefore easy to form the organic semiconductor layer only between the source and drain electrodes.

In the present invention, the organic semiconductor layer is preferably formed by an additive method using the source and drain electrodes as the dividing walls. Here, the additive method means a method that can provide an organic semiconductor material only between source and drain electrodes and can also provide an organic semiconductor material selectively such that an organic semiconductor layer pattern-wise only between source and drain electrodes. The reason why the organic semiconductor layer is preferably formed by an additive method using the source and drain electrodes as the dividing walls is that if the organic semiconductor layer is formed by this additive method, this makes it easy to form the organic semiconductor layer only between the source and drain electrodes.

Also, though, in conventional methods, it is necessary to form the dividing wall by using a resin or the like to carry out the patterning of the organic semiconductor layer using the additive method, the organic semiconductor layer can be formed directly pattern-wise by using the source and drain electrodes as the dividing walls, bringing about high productivity.

Moreover, in the present invention, the source and drain electrodes are porous bodies. Therefore, in the case of forming the organic semiconductor layer by the additive method, the source and drain electrodes absorb the organic semiconductor material applied by the additive method and stably support the organic semiconductor material between them, which makes it easy to form the organic semiconductor layer stably.

In the present invention, the additive method is preferably an ink jet method. This is because when the additive method is an ink jet method, the organic semiconductor material can be provided in a desired amount with high positional accuracy and it is therefore more easy to form the organic semiconductor layer only between the source and drain electrodes when, for example, the organic semiconductor device of the present invention is produced.

In the present invention, the organic semiconductor layer is preferably formed by an additive method using the source and drain electrodes as the dividing walls, and the surface of the gate insulation layer preferably has liquid repellency to a coating solution for forming the organic semiconductor layer to be used in the additive method. This is because this prevents the coating solution for forming the organic semiconductor layer from wetting the surface and spreading on an area other than the area between the source and drain electrodes when the organic semiconductor layer is formed in the process of manufacturing the organic semiconductor device of the present invention, which ensures that the organic semiconductor layer can be formed only between the source and drain electrodes with ease.

In the present invention, the organic semiconductor layer is preferably formed by an additive method using the source and drain electrodes as the dividing walls, and the surface of the substrate preferably has liquid repellency to a coating solution for forming the organic semiconductor layer to be used in the additive method. This is because this prevents the coating solution for forming the organic semiconductor layer from wetting the surface and spreading on an area other than the area between the source and drain electrodes when the organic semiconductor layer is formed in the process of manufacturing the organic semiconductor device of the present invention, which ensures that the organic semiconductor layer can be formed only between the source and drain electrodes with ease.

Furthermore, in the present invention, the liquid repellency is preferably on such a level that the contact angle is 40° or more with the coating solution for forming the organic semiconductor layer. This is because when the organic semiconductor layer is formed in the process of manufacturing the organic semiconductor device of the present invention, the coating solution for forming the organic semiconductor layer that has sunk in the source and drain electrodes can be prevented from bleeding out of the electrodes and therefore the organic semiconductor layer can be prevented from being formed in an area other than the area between the source and drain electrodes.

The present invention also provides a manufacturing method of an organic semiconductor device, the method comprising: a gate electrode formation step of using a substrate to form a gate electrode on the substrate; a gate insulation formation step of forming a gate insulation layer on the gate electrode; a source/drain electrode formation step of forming source and drain electrodes which are porous bodies and are formed on the gate insulation layer; and an organic semiconductor layer formation step of forming an organic semiconductor layer made of an organic semiconductor material only between the source and drain electrodes.

The present invention also provides a manufacturing method of an organic semiconductor device, the method comprising: a source/drain electrode formation step of using a substrate to form source and drain electrodes which are porous bodies and are formed on the substrate; an organic semiconductor layer formation step of forming an organic semiconductor layer made of an organic semiconductor material only between the source and drain electrodes; a gate insulation layer formation step of forming a gate insulation layer on the organic semiconductor layer; and a gate electrode formation step of forming a gate electrode on the gate insulation layer.

According to the present invention, the organic semiconductor layer made of the organic semiconductor material is formed only between the source and drain electrodes, whereby an organic semiconductor device superior in on-off ratio can be produced.

According to the present invention, the source and drain electrode formation step is to form the source and drain electrodes which are porous bodies, and the source electrode and drain electrodes absorb the organic semiconductor material provided by the additive method, so that the organic semiconductor material can be stably held between both electrodes when the organic semiconductor layer is formed by the additive method in, for example, the step of forming the organic semiconductor layer. This enables the organic semiconductor layer to be formed stably.

Since the organic semiconductor material can be stably held between the electrodes, the height of the source and drain electrodes can be reduced, and the formation of the source and drain electrodes can be thereby made easy. Also, since the surface of the organic semiconductor device of the present invention can be made flat, it is possible to form a passivation layer and a counter electrode with ease.

In the present invention, the organic semiconductor layer formation step is preferably a step of forming the organic semiconductor layer made of the organic semiconductor material by the additive method using the source and drain electrodes as the dividing walls. This is because when the organic semiconductor layer formation step is a step of forming the organic semiconductor layer made of the organic semiconductor material by the additive method, the organic semiconductor layer can be stably formed only between the source and drain electrode in the organic semiconductor layer formation step.

Though in conventional methods, it is necessary to form the dividing wall by using a resin or the like to carry out the patterning of the organic semiconductor layer using the additive method, the organic semiconductor layer can be formed directly pattern-wise by using the source and drain electrodes as the dividing walls, bringing about high productivity.

The source and drain electrode formation step is to form the source and drain electrodes which are porous bodies, and therefore, the source and drain electrodes absorb the organic semiconductor material provided by the additive method, so that the organic semiconductor material can be held between both electrodes since the organic semiconductor layer is formed by the additive method in the step of forming the organic semiconductor layer, making it possible to stably form the organic semiconductor layer with ease.

In the present invention, the additive method is preferably an ink jet method. This is because when the additive method is an ink jet method, the organic semiconductor material can be provided in a desired amount with high positional accuracy and it is therefore more easy to form the organic semiconductor layer only between the source and drain electrodes when, for example, the organic semiconductor device of the present invention is produced in the organic semiconductor formation step.

In the present invention, the source/drain electrode formation step is preferably a step of forming source and drain electrodes by a coating method of applying and baking a coating solution containing metal nanoparticles. This is because the source and drain electrodes can be made as a porous body by forming the source and drain electrodes using a coating method of applying and baking a coating solution containing metal nanoparticles. This is also because in the case of forming the organic semiconductor layer by the additive method in the organic semiconductor layer formation step, the source and drain electrodes which are porous bodies absorb the organic semiconductor material provided by the additive method, so that the organic semiconductor material can be held between both electrodes stably, making it possible to stably form the organic semiconductor layer only between the source and drain electrodes with ease.

Also, as mentioned above, since the organic semiconductor material can be stably held between the electrodes, the height of the source and drain electrodes can be reduced, and the formation of the source and drain electrodes can be thereby made easy. Also, since the surface of the organic semiconductor device of the present invention can be made flat, it is possible to form a passivation layer and a counter electrode with ease.

In the present invention, preferably the organic semiconductor formation step is to form the organic semiconductor layer by an additive method using the source and drain electrodes as the dividing walls, and the surface of the gate insulation layer to be formed in the gate insulation layer formation step preferably has liquid repellency to a coating solution for forming the organic semiconductor layer to be used in the additive method. This is because the coating solution for forming the organic semiconductor layer is prevented from wetting the surface and spreading on an area other than the area between the source and drain electrodes, which ensures that the organic semiconductor layer can be formed only between the source and drain electrodes with ease when the organic semiconductor layer is formed in the organic semiconductor layer formation step.

In the present invention, preferably the organic semiconductor layer formation step is to form the organic semiconductor layer by an additive method using the source and drain electrodes as the dividing walls, and the surface of the substrate has liquid repellency to a coating solution for forming the organic semiconductor layer to be used in the additive method. This is because the coating solution for forming the organic semiconductor layer is prevented from wetting the surface and spreading on an area other than the area between the source and drain electrodes, which ensures that the organic semiconductor layer can be formed only between the source and drain electrodes with ease when the organic semiconductor layer is formed in the organic semiconductor layer formation step.

Moreover, in the present invention, the source/drain electrodes formation step is preferably a step of forming source and drain electrodes by a coating method of applying and baking a coating solution containing metal nanoparticles, and the liquid repellency is preferably on such a level that the contact angle is 40° or more with the coating solution for forming the organic semiconductor layer. This is because when the organic semiconductor layer is formed in the process of manufacturing the organic semiconductor layer of the present invention, the coating solution for forming the organic semiconductor layer that has sunk in the source and drain electrodes can be prevented from bleeding out of the electrodes and therefore the organic semiconductor layer can be prevented from being formed in an area other than the area between the source and drain electrodes.

The present invention also provides an organic transistor array using the organic semiconductor device according to the present invention wherein two or more of the organic semiconductor transistors are formed on the substrate. The present invention ensures that an organic transistor array superior in on-off ratio can be obtained since the organic semiconductor device according to the present invention is used.

Moreover, the present invention provides a display using the organic transistor array according to the present invention. According to the present invention, the organic transistor array according to the present invention is used and therefore, a display having a superior display performance can be obtained.

The present invention produces such an effect as to provide an organic semiconductor device containing an organic semiconductor transistor reduced in off-current since the organic semiconductor layer is formed only between the source and drain electrodes.

### BRIEF DESCRIPTION OF THE DRAWINGS

FIG. 1 is a schematic view showing an example of an organic semiconductor device according to the present invention;

FIG. 2 is a schematic view showing an example of an organic semiconductor transistor used in the present invention;

FIG. 3 is a schematic view showing an example of a method of producing an organic semiconductor device according to a first embodiment of the present invention;

FIG. 4 is a schematic view showing an example of a method of producing an organic semiconductor device according to a second embodiment of the present invention; and

FIG. 5 is a schematic view showing an example of a general semiconductor transistor.

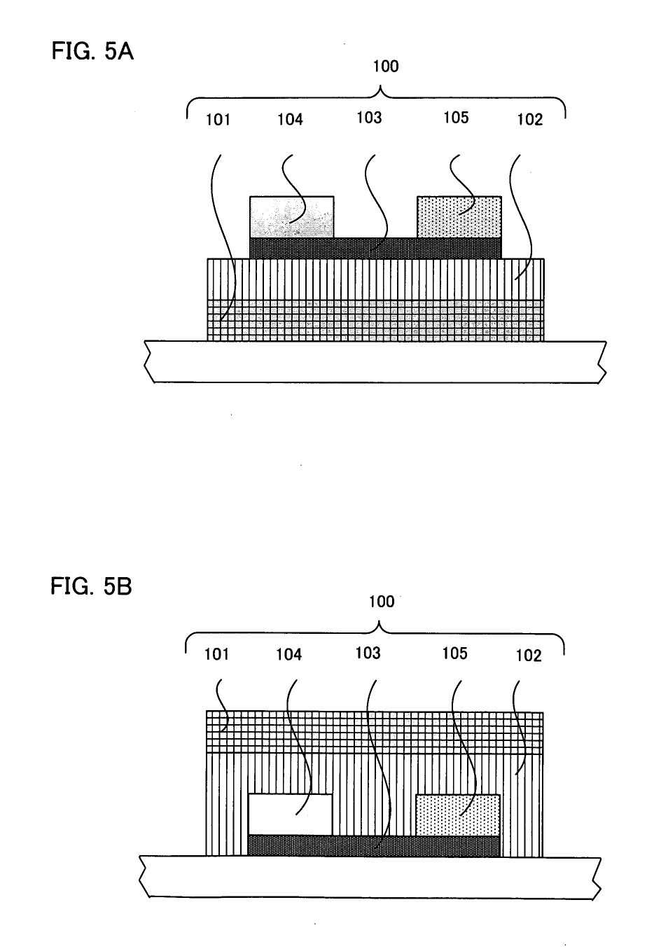

### DESCRIPTION OF THE PREFERRED EMBODIMENT

The present invention relates to an organic semiconductor device, a manufacturing method of the organic semiconductor device, an organic transistor array and a display. The organic semiconductor device of the present invention and the manufacturing method of the organic semiconductor device will be described.

A. Organic Semiconductor Device

First, the organic semiconductor device of the present invention will be described. The organic semiconductor device of the present invention is provided with a substrate and an organic semiconductor transistor. Here, the organic semiconductor transistor includes those of a bottom gate structure type and a top gate structure type. When the organic semiconductor transistor has a bottom gate structure, the organic semiconductor device of the present invention comprises a substrate and an organic semiconductor transistor including a gate electrode formed on the substrate, a gate insulation layer formed on the gate electrode, a source electrode and a drain electrode which are porous bodies and are formed on the gate insulation layer and an organic semiconductor layer which is made of an organic semiconductor material and formed only between the source and drain electrodes. When the organic semiconductor transistor has a top gate structure, the organic semiconductor device of the present invention comprises a substrate and an organic semiconductor transistor including a source electrode and a drain electrode which are porous bodies and are formed on the substrate, an organic semiconductor layer which is made of an organic semiconductor material and formed only between the source and drain electrodes, a gate insulation layer formed on the organic semiconductor layer formed on the organic semiconductor layer and a gate electrode formed on the gate insulation layer.

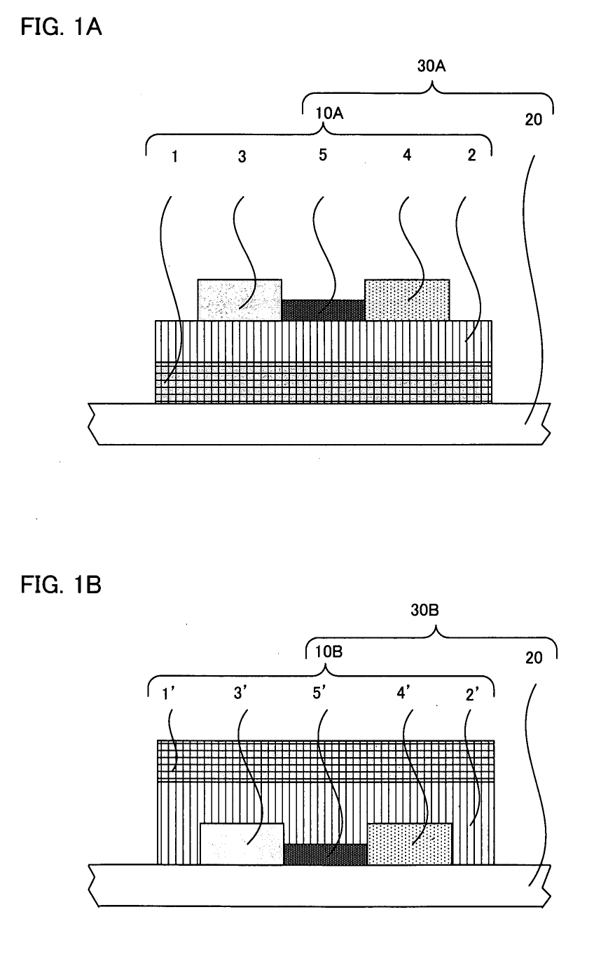

Next, the organic semiconductor device of the present invention will be described with reference to the drawings. FIG. 1 is a schematic view showing an example of the organic semiconductor transistor of the present invention. When the organic semiconductor device of the present invention is provided with an organic semiconductor transistor having a bottom gate structure as shown in FIG. 1A, the organic semiconductor device 30A of the present invention is provided with a substrate 20 and an organic semiconductor transistor 10A having a bottom gate structure.

Here, the organic semiconductor transistor 10A having a bottom gate structure is provided with a gate electrode 1 formed on the substrate 20, a gate insulation layer 2 formed on the gate electrode 1, a source electrode 3 and a drain electrode 4 which are porous bodies and are formed on the gate insulation layer 2 and an organic semiconductor layer 5 which is made of an organic semiconductor material and formed only between the source electrode 3 and drain electrode 4.

Also, when the organic semiconductor device of the present invention is provided with an organic semiconductor transistor having a top gate structure as shown in FIG. 1B, the organic semiconductor device 30B of the present invention is provided with a substrate 20 and an organic semiconductor transistor 10A having a top gate structure.

In this case, the organic semiconductor transistor 10B having a top gate structure is provided with a source electrode 3′ and a drain electrode 4′ which are porous bodies and are formed on the substrate 20, an organic semiconductor layer 5′ which is made of an organic semiconductor material and formed only between the source and drain electrodes 3′ and 4′, a gate insulation layer 2′ formed on the organic semiconductor layer 5′ and a gate electrode 1′ formed on the gate insulation layer 2′.

According to the present invention, the organic semiconductor layer is formed only between the source and drain electrodes and therefore the amount of drain current when the device is off, that is, off-current can be made to be low. Also, the present invention ensures that the source electrode and drain electrode are respectively made of a porous body, and therefore, when, for example, the organic semiconductor device of the present invention is produced and the organic semiconductor layer is formed by an additive method, the source and drain electrodes can absorb the organic semiconductor material and support the organic semiconductor material stably between them, which makes it easy to form the organic semiconductor layer stably.

Moreover, since the organic semiconductor material can be held stably between the electrodes, the height of the source and drain electrodes may be reduced, whereby the source and drain electrodes can be easily formed. Also, the surface of the organic semiconductor device of the present invention can be easily flattened, and therefore, a passivation layer and a counter electrode can be easily formed.

As is clear from the descriptions, an organic semiconductor device superior in on-off ratio can be obtained by the present invention.

The organic semiconductor device of the present invention is provided with a substrate and an organic semiconductor transistor.

Each structure of such an organic semiconductor device will be described.

1. Organic Semiconductor Transistor

First, the organic semiconductor transistor to be used in the present invention will be described. The organic semiconductor transistor to be used in the present invention may be classified into two types of transistors, that is, an organic semiconductor transistor having a bottom gate structure and an organic semiconductor transistor having a top gate structure.

The organic semiconductor transistor to be used in the present invention will be described in each type separately.

(1) Organic Semiconductor Transistor in a First Embodiment

The organic semiconductor transistor in this embodiment has a bottom gate structure. Specifically, the organic semiconductor transistor in this embodiment is provided with a gate electrode formed on a substrate which will be described later, a gate insulation layer formed on the gate electrode, a source electrode and a drain electrode which are porous bodies and are formed on the gate insulation layer and an organic semiconductor layer which is made of an organic semiconductor material and formed only between the source and drain electrodes.

As already described with reference to FIG. 1A, the organic semiconductor transistor in this embodiment has a structure in which the organic semiconductor transistor 10A is provided with a gate electrode 1 formed on the substrate 20 which will be described later, a gate insulation layer 2 formed on the gate electrode 1, a source electrode 3 and a drain electrode 4 which are porous bodies and are formed on the gate insulation layer 2 and an organic semiconductor layer 5 which is made of an organic semiconductor material and formed only between the source electrode 3 and drain electrode 4.

In this embodiment, the organic semiconductor layer is formed only between the source and drain electrodes and therefore, the amount of drain current when the device is off, that is, off-current can be made to be low.

The organic semiconductor transistor in this embodiment is provided with at least a gate electrode, a gate insulation layer, a source electrode/a drain electrode and an organic semiconductor layer.

Each structure to be used in the organic semiconductor transistor in this embodiment will be described.

(a) Organic Semiconductor Layer

First, the organic semiconductor layer used in this embodiment will be described. The organic semiconductor layer used in this embodiment is constituted of an organic semiconductor material and formed only between the source and drain electrodes which will be described later.

No particular limitation is imposed on the organic semiconductor material used in this embodiment insofar as it is a material capable of forming an organic semiconductor layer having desired semiconductor characteristics according to the use of the organic semiconductor device of the present invention, and organic semiconductor materials which are usually used for organic semiconductor transistors may be used. Examples of the organic semiconductor material may include π-electron conjugate type aromatic compounds, chain type compounds, organic pigments and organic silicon compounds. Specific examples of the organic semiconductor material may include low-molecular organic semiconductor materials such as pentacene and high-molecular type organic semiconductor materials, for example, polypyrroles such as polypyrrol, poly(N-substituted pyrrole), poly(3-substituted pyrrole) and poly(3,4-disubstituted pyrrole), polythiophenes such as polythiophene, poly(3-substituted thiophene), poly(3,4-disubstituted thiophene) and polybenzothiophene, polyisothianaphthenes such as polyisothianaphthene, polythenylenevinylenes such as polythenylenevinylene, poly(p-phenylenevinylenes) such as poly(p-phenylenevinylene), polyanilines such as polyaniline and poly(N-substituted aniline), polyacetylenes such as polyacetylene and polydiacetylene, and polyazulenes such as polyazulene.

Among these compounds, those which can be solubilized are preferably used in this embodiment. This is because the organic semiconductor layer can be formed only between the source and drain electrodes which will be described later since the organic semiconductor layer can be formed by the additive method which will be described later.

Also, no particular limitation is imposed on the thickness of the organic semiconductor layer to be used in this embodiment insofar as it is within the range where an organic semiconductor layer having desired semiconductor characteristics can be developed according to, for example, the type of the semiconductor material. Particularly, in this embodiment, the thickness of the organic semiconductor layer is preferably in a range from 1 nm to 1000 nm, more preferably in a range from 1 nm to 300 nm and particularly preferably in a range from 1 nm to 100 nm. When the thickness of the organic semiconductor exceeds the range, drain current is caused by the flow of current round through other routes, leading to an increase in off-current. When the thickness of the organic semiconductor is below the range, there is the possibility of existence of the places where the organic semiconductor layer is not in contact with the source and drain electrodes which will be described later.

No particular limitation is imposed on a method of forming the organic semiconductor layer used in this embodiment insofar as the organic semiconductor layer can be formed only between the source and drain electrodes. Examples of the method may include an additive method and photolithographic method. Particularly, it is preferable to form the organic semiconductor layer by an additive method using the source and drain electrode as the dividing walls. This is because the organic semiconductor layer is thereby easily formed only between the source and drain electrodes.

Though, in conventional methods, it is necessary to form the dividing wall by using a resin or the like to carry out the patterning of the organic semiconductor layer using the additive method, the organic semiconductor layer can be formed directly pattern-wise by using the source and drain electrodes as the dividing walls, bringing about high productivity.

In the present invention, the source electrode and drain electrode are respectively made of a porous body, and therefore, when, for example, the organic semiconductor layer is formed by an additive method, the source and drain electrodes can absorb the organic semiconductor material given by the additive method and support the organic semiconductor material stably between them, which makes it easy to form the organic semiconductor layer stably.

Here, the additive method means a method that can provide an organic semiconductor material only between source and drain electrodes and can also provide an organic semiconductor material selectively such that an organic semiconductor layer is formed pattern-wise only between source and drain electrodes. Specific examples of the additive method include printing methods such as an ink jet method, screen printing method and flexo-printing method. In this embodiment, the organic semiconductor material is preferably formed by an inkjet method. This is because when the additive method is an ink jet method, the organic semiconductor material can be provided in a desired amount with high positional accuracy and it is therefore more easy to form the organic semiconductor layer only between the source and drain electrodes when, for example, the organic semiconductor device of the present invention is produced.

(b) Source Electrode and Drain Electrode

Next, the source electrode and drain electrode to be used in this embodiment will be described. Though no particular limitation is imposed on the material of the source and drain electrodes to be used in this embodiment insofar as it is a porous body and a material having desired conductivity, those made of metal materials are usually used. As such a metal material, metal materials that are usually used for organic semiconductor transistors may be used. Examples of these materials which may be used in the present invention may include metal materials such as Ag, Au, Ta, Ti, Al, Zr, Cr, Nb, Hf, Mo, Mo—Ta alloys, ITO, IZO and conductive polymers such as PEDOT/PSS. Particularly, Ag is preferably used in this embodiment.

Here, the source and drain electrodes used in this embodiment are porous bodies as mentioned above. The term “porous” in the present invention indicates the state of a material with pores having a pore diameter just enough to contain the organic semiconductor material.

Also, there is no particular limitation to each thickness of the source and drain electrodes to be used in this embodiment insofar as it is larger than that of the organic semiconductor layer and is in a range where the organic semiconductor layer can be formed only between the source and drain electrodes. In this embodiment, the thickness of the source and drain electrodes is preferably in a range from 50 nm to 10000 nm, more preferably in a range from 100 nm to 2000 nm and particularly preferably in a range from 200 nm to 2000 nm. This is because if the thickness exceeds the range, there is the possibility that the formation of, for example, a passivation layer which will be described later is inhibited, whereas if the thickness is below the range, the organic semiconductor material bleeds out of the space between the source and drain electrodes and it is therefore difficult to form the organic semiconductor layer only between the source and drain electrodes, when the organic semiconductor material is provided by an additive method to form the organic semiconductor layer.

The source electrode and drain electrode used in this embodiment are porous bodies and this produces the effect of stably forming the organic semiconductor layer with ease, when the organic semiconductor layer is formed by an additive method in the case of producing, for example, the organic semiconductor device of the present invention.

Here, the reason why it is easy to stably form the organic semiconductor layer only between the source and drain electrodes since the source and drain electrodes are porous bodies is not clarified. However, the reason is considered to be as follows.

Since the source and drain electrodes are porous bodies, they absorb the organic semiconductor material in their pores and can stably support between the source and drain electrodes when the organic semiconductor material is provided by an additive method. This enables stable formation of the organic semiconductor layer between the source and drain electrodes.

Such an effect brings about the formation of the organic semiconductor layer only between both electrodes without any bleeding of the organic semiconductor layer from between both electrodes even in the case of using an ink jet method in which an organic semiconductor material put into the state of a liquid droplet having a diameter larger than the thickness of the source and drain electrodes is applied. In the case where the source and drain electrodes are not porous bodies, on the other hand, it is difficult to form the organic semiconductor material only between the electrodes because the organic semiconductor material put into the state of a liquid droplet provided by an ink jet method bleeds from between both electrodes if the thickness of the source and drain electrodes is not made larger.

Therefore, the source and drain electrodes are porous bodies and are therefore decreased in height, whereby the formation of the source and drain electrodes can be made ease. Further, the surface of the organic semiconductor device of the present invention can be easily flattened, and therefore, a passivation layer and a counter electrode can be easily formed.

In the case where the source and drain electrodes used in this embodiment are porous bodies, no particular limitation is imposed on the average pore diameter of the porous body insofar as the source and drain electrodes have desired conductivity and the pore diameter is determined by the size of the metal nanoparticles to be used.

Also, in this embodiment, the organic semiconductor material is preferably contained in pores of the source and drain electrodes. This is because the contact area between the organic semiconductor layer and the source and drain electrodes can be substantially increased, and therefore, the performance of the organic semiconductor transistor in this embodiment can be improved. This is also because if the organic semiconductor layer is formed such that the organic semiconductor material is contained in the source and drain electrodes, the organic semiconductor layer is easily formed only between the source and drain electrodes.

(c) Gate Electrode

Next, the gate electrode used in this embodiment will be described. There is no particular limitation to the gate electrode insofar as it is made of a material having desired conductivity. In this embodiment, metal materials usually used for organic semiconductor transistors may be used. Examples of these materials which may be used in the present invention may include metal materials such as Ag, Au, Ta, Ti, Al, Zr, Cr, Nb, Hf, Mo, Mo—Ta alloys, ITO, IZO and conductive polymers such as PEDOT/PSS.

The gate electrode used in this embodiment may be a porous body or may be nonporous body.

(d) Gate Insulation Layer

Next, the gate insulation layer to be used in this embodiment will be described. As the materials of the gate insulation layer, the same insulation materials that are used in general organic semiconductor transistors may be used. As such an insulation material, organic materials such as acryl type resins, phenol type resins, fluorine type resins, epoxy type resins, cardo-type resins, vinyl type resins, imide type resins and novolac resins and inorganic materials such as SiO₂, SiNₓ and Al₂O₃ may be used.

Also, the gate insulation layer having a liquid repellent surface is preferably used in this embodiment. Particularly, when the organic semiconductor layer used in this embodiment is formed by the above additive method, the gate insulation layer used in this embodiment preferably has liquid repellency to a coating solution for forming the organic semiconductor layer which is to be applied by this additive method. If the gate insulation layer has such liquid repellency, this prevents the coating solution for forming the organic semiconductor layer from wetting the surface and spreading on an area other than the area between the source and drain electrodes when the organic semiconductor layer is formed during the course of manufacturing an organic semiconductor transistor in this embodiment, which ensures that the organic semiconductor layer can be formed only between the source and drain electrodes with ease. Also, this is because the semiconductor characteristics of the organic semiconductor layer to be formed on the gate insulation layer can be improved.

Here, the coating solution for forming the organic semiconductor layer is one which is applied to the area between the source and drain electrodes when the organic semiconductor layer is formed by the additive method and contains the organic semiconductor material. The word “has liquid repellency to a coating solution for forming the organic semiconductor layer” means that the contact angle of the surface of the gate insulation layer with the coating solution for forming the organic semiconductor layer is 40° or more.

As the contact angle, a value measured at ambient temperature (23° C.) by using prop Master 700 manufactured by Kyowa Interface Science Co., Ltd. is used.

When the gate insulation layer having a liquid repellent surface is used in this embodiment, no particular limitation is imposed on the level of the liquid repellency. Particularly, when the above additive method is used as the method of forming the organic semiconductor layer, the gate insulation layer preferably has a liquid repellency to the extent that the coating solution for forming the organic semiconductor layer applied by the additive method is prevented from wetting and spreading on an area other than the area between the source and drain electrodes. This is because if the gate insulation layer has such a liquid repellency, the organic semiconductor layer can be formed only between the source and drain electrodes more easily.

Here, specific liquid repellency is appropriately adjusted according to the composition of the coating solution for forming the organic semiconductor layer and the forms of the source and drain electrodes. When porous bodies are used as the source and drain electrodes, the liquid repellency is on such a level that the contact angle of the surface of the gate insulation layer with the coating solution for forming the organic semiconductor layer is preferably 40° or more, more preferably in a range from 40° to 60° and particularly preferably in a range from 40° to 45°.

If the contact angle falls in the range, the coating solution for forming the organic semiconductor layer that has sunk in the source and drain electrodes can be prevented from bleeding out of the electrodes when the organic semiconductor layer is formed in the process of manufacturing the organic semiconductor device of the present invention, and therefore, the organic semiconductor layer can be prevented from being formed in an area other than the area between the source and drain electrodes.

When nonporous bodies are used as the source and drain electrodes, the liquid repellency is on such a level that the contact angle of the surface of the gate insulation layer with the coating solution for forming the organic semiconductor layer is preferably 50° or more, more preferably in a range from 50° to 60° and particularly preferably in a range from 55° to 60°.

As the contact angle, values obtained by measuring according to the measuring method and measuring condition are used.

When the gate insulation layer has a liquid repellency on its surface, there is no particular limitation to the structure of the gate insulation layer provided with liquid repellency insofar as this structure can develop desired liquid repellency. Examples of the structure may include a structure in which the surface of the gate insulation layer is processed by liquid repellent treatment, a structure in which the gate insulation layer is provided with a liquid repellent layer containing a liquid repellent material on the surface thereof, a structure in which the gate insulation layer contains a liquid repellent material and a structure in which a desired liquid repellent material is used as the structural material of the gate insulation layer. A gate insulation layer having any of these structures may be preferably used in this embodiment. Among these structures, the structure in which a material having desired liquid repellency is used as the structural material of the gate insulation layer is preferable.

(2) Organic Semiconductor Transistor in a Second Embodiment

The organic semiconductor transistor of this embodiment has a top gate structure. Specifically, the organic semiconductor transistor in this embodiment is provided with a source electrode and a drain electrode which are porous bodies and are formed on a substrate which will be described later, an organic semiconductor layer which is made of an organic semiconductor material and formed only between the source and drain electrodes, a gate insulation layer formed on the organic semiconductor layer and a gate electrode formed on the gate insulation layer.

As already described with reference to FIG. 1B, the organic semiconductor transistor in this embodiment includes the structure in which the organic semiconductor transistor 10B is provided with a source electrode 3′ and a drain electrode 4′ which are porous bodies and are formed on a substrate 20 which will be described later, an organic semiconductor layer 5′ which is made of an organic semiconductor material and formed only between the source electrode 3′ and drain electrode 4′, a gate insulation layer 2′ formed on the organic semiconductor layer 5′ and a gate electrode 1′ formed on the gate insulation layer 2′.

In this embodiment, the organic semiconductor layer is formed only between the source and drain electrodes and therefore, the amount of drain current when the device is off, that is, off-current can be made to be low.

The organic semiconductor transistor in this embodiment is provided with at least a gate electrode, a gate insulation layer, an organic semiconductor layer and a source electrode/a drain electrode. Each structure to be used in this embodiment is the same as that described in the paragraph “(1) Organic semiconductor transistor in a first embodiment” and descriptions of this structure will be omitted here.

Also, the organic semiconductor transistor used in this embodiment may have structures other than the gate electrode, gate insulation layer, organic semiconductor layer and source and drain electrodes. Each structure to be used in this embodiment is the same as that described in the paragraph “(1) Organic semiconductor transistor in a first embodiment” and descriptions of this structure will be omitted here.

(3) Others

No particular limitation is imposed on the organic semiconductor transistor used in the present invention insofar as it has the above structure and also has a bottom gate structure or a top gate structure and the organic semiconductor transistor may have other structures.

There is no particular limitation to the other structure insofar as it can provide the organic semiconductor device of the present invention with a desired function. Examples of the other structure that is preferably used in the organic semiconductor layer among these structures may include a passivation layer which is formed in such a manner as to cover the organic semiconductor layer to prevent the organic semiconductor layer from being exposed to moisture and the like contained in the air. If such a passivation layer is disposed, the organic semiconductor transistor to be used in the present invention may be reduced in deterioration with time.

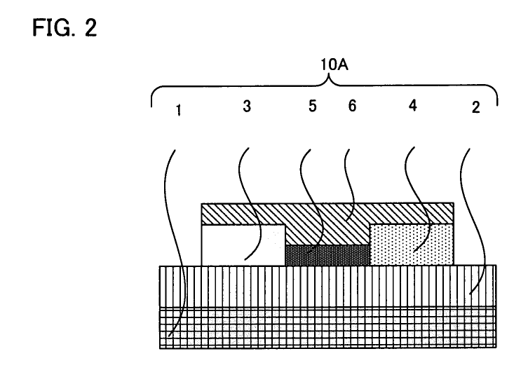

FIG. 2 is a schematic view showing an example when the organic semiconductor transistor to be used in the present invention is covered with the passivation layer. As illustrated in FIG. 2, the organic semiconductor transistor 10A to be used in the present invention may be provided with a passivation layer 6 formed so as to cover the organic semiconductor layer 5.

FIG. 2 is an example of the organic semiconductor transistor having a bottom gate structure. When the organic semiconductor transistor has a top gate structure, the passivation layer may also be formed in the same manner.

No particular limitation is imposed on the material constituting the passivation layer to be used in the present invention insofar as the organic semiconductor layer is prevented to a desired extent from being exposed to moisture contained in the air. Examples of the material constituting the passivation layer may include resin materials such as acryl type resins, phenol type resins, fluorine type resins, epoxy type resins, cardo-type resins, vinyl type resins, imide type resins and novolac type resins.

Also, the organic semiconductor device of the present invention has a structure in which plural organic semiconductor transistors are disposed on a substrate which will be described later. Here, no particular limitation is imposed on the structure in which the plural organic semiconductor transistors are disposed on a substrate and these plural semiconductor transistors may be disposed in a desired configuration according to the use or the like of the organic semiconductor device of the present invention.

2. Substrate

Next, the substrate to be used in the organic semiconductor device of the present invention will be described. The substrate used in the present invention serves to support the organic semiconductor transistor.

As the substrate used in the present invention, those having a desired function according to the use of the organic semiconductor device of the present invention may be used. As such a substrate, a rigid substrate having no flexibility such as a glass substrate may be used, or a flexible substrate such as a plastic resin film may be used. Although either of these rigid substrate or flexible substrate is used in the present invention, a flexible substrate is preferably used. This is because if such a flexible substrate is used, the organic semiconductor device of the present invention can be produced by a Roll-to-Roll process and the organic semiconductor device of the present invention may be manufactured with high productivity.

Here, examples of the plastic resin may include PET, PEN, PES, PI, PEEK, PC, PPS and PEI.

Also, the substrate used in the present invention may have a monolayer structure or a structure obtained by laminating plural layers. As the substrate having the structure in which plural layers are laminated, those having, for example, a structure in which barrier layers made of metal materials are laminated on the substrate made of a plastic resin may be given as examples. Here, it is pointed out that the substrate made of a plastic resin has an advantage in that the organic semiconductor device of the present invention is made to be a flexible one, but, on the contrary, has the drawback that the surface of the substrate is easily damaged on forming the source and drain electrodes. However, the use of the substrate produced by laminating barrier layers has an advantage in that the drawback as stated above can be solved even in the case of using a base material made of the plastic resin.

Also, the thickness of the substrate used in the present invention is usually 1 mm or less and more preferably in a range from 50 μm to 700 μm.

Here, when the substrate used in the present invention has a structure in which plural layers are laminated, the thickness means the total thickness of these plural layers.

When as the organic semiconductor transistor, the organic semiconductor transistor of the second embodiment is used, the surface of the substrate used in the present invention preferably has liquid repellency. Particularly when the organic semiconductor layer used in the organic semiconductor transistor of the second embodiment is formed by the above additive method, the substrate to be used in the present invention preferably has liquid repellency to the coating solution for forming the organic semiconductor layer to be applied by the additive method. This is because if the substrate has such liquid repellency, the coating solution for forming the organic semiconductor layer is prevented from wetting and spreading on an area other than the area between the source and drain electrodes in the process of manufacturing the organic semiconductor transistor of the second embodiment, and therefore, the organic semiconductor layer can be formed only between the source and drain electrodes more easily. Also, the semiconductor characteristics of the organic semiconductor layer formed on the substrate can be improved.

Here, the coating solution for forming the organic semiconductor layer and the meaning of the word “has liquid repellency to the coating solution for forming the organic semiconductor layer” are the same as those described in the paragraph “(1) Organic semiconductor transistor in a first embodiment” and descriptions of them will be omitted here.

When a substrate having a liquid repellent surface is used in this embodiment, there is no limitation to the level of the liquid repellency. Particularly, when the above additive method is used as a method of forming the organic semiconductor layer used in the organic semiconductor transistor of the second embodiment, the substrate preferably has a liquid repellency on such a level that the coating solution for forming the organic semiconductor layer applied by the additive method is prevented from wetting the surface and spreading on an area other than the area between the source and drain electrodes, which ensures that the organic semiconductor layer can be formed only between the source and drain electrodes with ease.

Here, the specific level of the liquid repellency is properly adjusted according to, for example, the composition of the coating solution for forming the organic semiconductor layer and the forms of source and drain electrodes. When porous bodies are used as the source and drain electrodes, the liquid repellency is on such a level that the contact angle of the surface of the substrate with the coating solution for forming the organic semiconductor layer is preferably 40° or more, more preferably in a range from 40° to 60° and particularly preferably in a range from 40° to 45°. If the contact angle falls in the range, the coating solution for forming the organic semiconductor layer that has sunk in the source and drain electrodes can be prevented from bleeding out of the electrodes when the organic semiconductor layer is formed in the process of manufacturing the organic semiconductor transistor of the present invention, and therefore, the organic semiconductor layer can be prevented from being formed in an area other than the area between the source and drain electrodes.

When nonporous bodies are used as the source and drain electrodes, the liquid repellency is on such a level that the contact angle of the surface of the gate insulation layer with the coating solution for forming the organic semiconductor layer is preferably 50° or more, more preferably in a range from 50° to 60° and particularly preferably in a range from 55° to 60°.

As the contact angle, values obtained by measuring according to the measuring method and measuring condition are used.

When the gate insulation layer has a liquid repellency on its surface, there is no particular limitation to the structure of the substrate provided with liquid repellency insofar as that structure can develop desired liquid repellency. Examples of the structure may include a structure in which the surface of the substrate is processed by liquid repellent treatment, a structure in which the substrate is provided with a liquid repellent layer containing a liquid repellent material on the surface thereof, a structure in which the substrate contains a liquid repellent material and a structure in which a desired liquid repellent material is used as the structural material of the substrate. A substrate having any of these structures may be preferably used in this embodiment. Among these structures, the structure in which a material having desired liquid repellency is used as the structural material of the substrate is preferable.

3. Application of the Organic Semiconductor Device

With regard to the application of the organic semiconductor device of the present invention, it may be used as a TFT array substrate of a display device using a TFT system. Examples of such a display device may include a liquid crystal display device, electrophoresis display device and organic EL display device.

4. Manufacturing Method of the Organic Semiconductor Device

As the manufacturing method of an organic semiconductor device according to the present invention, the methods to be described in the following paragraph “B. Manufacturing method of an organic semiconductor device” may be mentioned.

B. Manufacturing Method of an Organic Semiconductor Device

Next, the manufacturing method of an organic semiconductor device according to the present invention will be described. In the manufacturing method of an organic semiconductor device according to present invention, an organic semiconductor device comprising a substrate and an organic semiconductor transistor formed on the substrate is produced. Here, the manufacturing method of an organic semiconductor device may include two embodiments by the structure of the organic semiconductor transistor. Specifically, the manufacturing method of an organic semiconductor device according to the present invention may be roughly classified into a first embodiment of manufacturing an organic semiconductor device provided with an organic semiconductor transistor having a bottom gate structure and a second embodiment of manufacturing an organic semiconductor device provided with an organic semiconductor transistor having a top gate structure.

Therefore, the manufacturing method of an organic semiconductor device of the present invention will be described in each embodiment separately.

B-1: Manufacturing Method of an Organic Semiconductor Device in a First Embodiment

First, a manufacturing method of an organic semiconductor device according to a first embodiment will be described. The manufacturing method of the organic semiconductor device in this embodiment is a method of manufacturing an organic semiconductor device provided with an organic semiconductor transistor having a bottom gate structure. Specifically, the manufacturing method of an organic semiconductor device in this embodiment comprises a gate electrode formation step of using a substrate to form a gate electrode on the substrate, a gate insulation layer formation step of forming a gate insulation layer on the gate electrode, a source/drain electrode formation step of forming source and drain electrodes which are porous bodies on the gate insulation layer and an organic semiconductor layer formation step of forming an organic semiconductor layer made of an organic semiconductor material only between the source and drain electrodes.

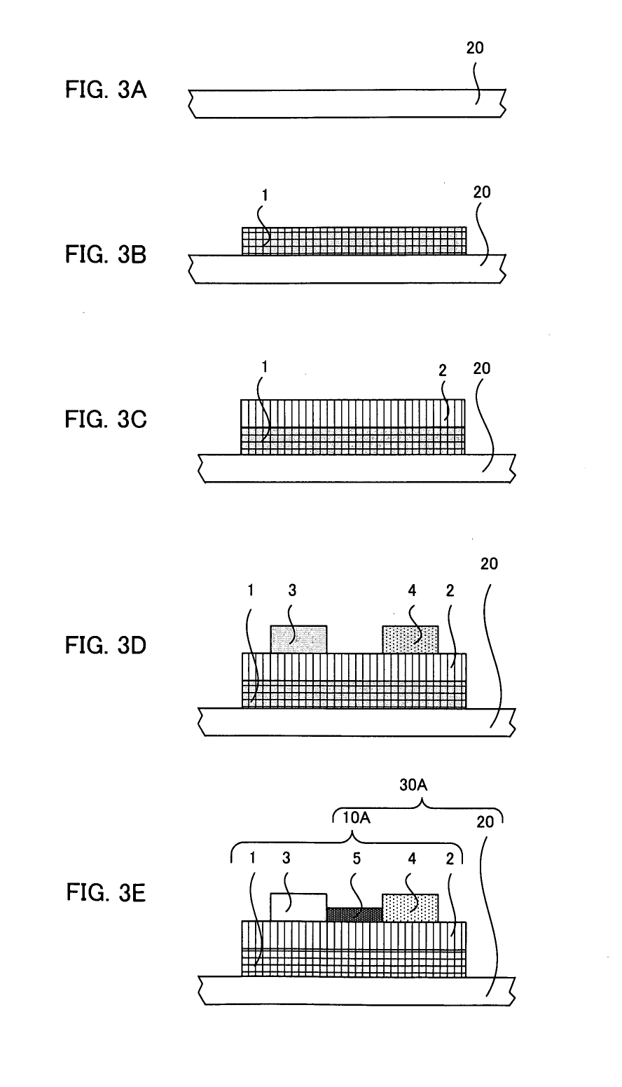

The manufacturing method of an organic semiconductor device according to this embodiment will be described with reference to the drawings. FIG. 3 is a schematic view showing an example of the manufacturing method of an organic semiconductor device of this embodiment. As illustrated in FIG. 3, the manufacturing method of the organic semiconductor device of this embodiment comprises a gate electrode formation step (FIG. 3B) of using a substrate 20 (FIG. 3A) to form a gate electrode 1 on the substrate 20, a gate insulation layer formation step (FIG. 3C) of forming a gate insulation layer 2 on the gate electrode 1, a source/drain electrode formation step (FIG. 3D) of forming source and drain electrodes (3, 4) which are porous bodies and an organic semiconductor layer formation step (FIG. 3E) of forming an organic semiconductor layer 5 made of an organic semiconductor material only between the source and drain electrodes 3 and 4, to manufacture an organic semiconductor device 30A having formed thereon an organic semiconductor transistor 10A having a bottom gate structure on the substrate 20.

The manufacturing method of an organic semiconductor device in this embodiment ensures that since the organic semiconductor layer made of an organic semiconductor material is formed only between the source and drain electrodes in the organic semiconductor layer formation step and therefore, an organic semiconductor device superior in on-off ratio can be manufactured.

Also, according to this embodiment, the source and drain electrodes which are porous bodies are formed in the source/drain electrode formation step. Therefore, these electrodes absorb the organic semiconductor material provided by the additive method and can stably support between the source and drain electrodes when the organic semiconductor layer is formed using the additive method in the organic semiconductor layer formation step. Therefore, the organic semiconductor layer can be formed stably with ease.

Moreover, the organic semiconductor material can be retained stably between the electrodes as mentioned above. Therefore, the source and drain electrodes are decreased in height, whereby the formation of the source and drain electrodes can be made ease. Also, the surface of the organic semiconductor device of the present invention can be easily flattened, and therefore, a passivation layer and a counter electrode can be easily formed.

The manufacturing method of an organic semiconductor device according to this embodiment comprises at least the gate electrode formation step, the gate insulation layer formation step, the source/drain electrode formation step and the organic semiconductor layer formation step, and may comprise other steps according to the need.

Each step used in this embodiment will be described in detail.

1. Gate Electrode Formation Step

First, the gate electrode formation step used in this embodiment will be described. This step is a step of using a substrate to form a gate electrode on the substrate.

In this step, no particular limitation is imposed on the method of forming the gate electrode on the substrate insofar as it is a method capable of forming a gate electrode having a desired form according to the type of material constituting the gate electrode. Examples of such a method may include a vacuum deposition method and a coating method in which metal nanoparticles are applied and baked to form a gate electrode.

Also, in this step, a gate electrode is formed pattern-wise on the substrate in usual. The method forming a gate insulation layer pattern-wise may be a method in which after a gate electrode is formed on the entire surface of the substrate, it is patterned. Or, a method may be adopted in which a pattern-wise gate electrode is formed directly on the substrate.

Here, as a method of patterning the gate electrode, a lithographic method is usually used and particularly a photolithographic method using a photoresist is preferably used.

On the other hand, as a method of forming a pattern-wise gate electrode directly, a printing method such as a screen printing method or ink jet method, a mask vapor deposition method or the like is preferably used.

The metal material constituting the substrate or gate electrode is the same as that described in the paragraph “A. Organic semiconductor device” and therefore, descriptions of this metal material are omitted here.

2. Gate Insulation Layer Formation Step

Next, the gate insulation layer formation step used in this embodiment will be described. This step is a step of forming a gate insulation layer including an insulation material on the gate electrode.

There is no particular limitation to a method of forming the gate insulation layer in this step insofar as it is a method of forming a gate insulation layer which contains an insulation material and has desired insulation characteristics. When, for example, an organic material is used as the insulation material, a method in which the organic material is dissolved in a solvent to prepare a coating solution for forming the gate insulation layer, which is then applied so as to cover the gate electrode may be given as examples of such a method.

No particular limitation is imposed on a coating system used to apply the coating solution for forming the gate insulation layer insofar as a coating film having a uniform thickness can be formed in accordance with, for example, the viscosity of the coating solution for forming the gate insulation layer. Examples of the coating system may include coating methods such as a spin coating method, die coating method, roll coating method, bar coating method, LB method, dip coating method, spray coating method, blade coating method and cast method and printing methods such as an ink jet method, screen printing method, pad printing method, flexo printing method, micro-contact printing method, gravure printing method, offset printing method and gravure-offset printing method.

Also, when an inorganic material is used as the insulation material, a CVD method or the like may be used.

The insulation material to be used for the gate insulation layer is the same as that described in the paragraph “A. Organic semiconductor device” and descriptions of the insulation material are omitted here.

3. Source/Drain Electrode Formation Step

Next, the source/drain electrode formation step used in this embodiment will be described. This step is a step of forming porous source and drain electrodes on the gate insulation layer.

In this step, there is no particular limitation is imposed on the method of forming the source and drain electrodes insofar as it can form the source electrode and the drain electrode at a desired interval (channel). Examples of such a formation method may include a coating method in which a coating solution containing metal nanoparticles is applied and baked to form these electrodes.

In the present invention, the source/drain electrode formation step is preferably a step of forming the source and drain electrodes by a coating method in which a coating solution containing metal nanoparticles is applied and baked. This is because if the source and drain electrodes are formed by such a coating method in which a coating solution containing metal nanoparticles is applied and baked, the source and drain electrodes can be formed as porous bodies with ease. When the organic semiconductor layer formation step which will be described later is a step of forming the organic semiconductor layer by the additive method, the source and drain electrodes absorb the organic semiconductor material provided by the additive method and can stably support the organic semiconductor material between the source and drain electrodes, making it possible to form the organic semiconductor layer stably only between both electrodes with ease.

Moreover, the organic semiconductor material can be retained stably between the electrodes as mentioned above. Therefore, the source and drain electrodes can be decreased in height, whereby the formation of the source and drain electrodes can be made ease. Further, the surface of the organic semiconductor device of the present invention can be easily flattened, and therefore, a passivation layer and a counter electrode can be easily formed.

In the coating method in which a coating solution containing metal nanoparticles is applied and baked, the coating solution containing metal nanoparticles is applied and then baked. More specifically, the coating method involves at least a metal nanoparticle coating solution formation step of dispersing metal nanoparticles in a solvent to form a metal nanoparticle coating solution, a coating step of coating the gate insulation layer with the metal nanoparticle coating solution to form a coating film and a baking step of baking the formed metal nanoparticle coating film. The coating method in which a coating solution containing metal nanoparticles is applied and baked in this manner will be described.

(Metal Nanoparticle Coating Solution Formation Step)

First, the metal nanoparticle coating solution formation step used in the coating method in which a coating solution containing metal nanoparticles is applied and baked will be described. This step is used to disperse metal nanoparticles in a solvent to prepare a metal nanoparticle coating solution.

There is no particular limitation to the average particle diameter of the metal nanoparticles used in this step insofar as it is capable to forming a porous body. In this step, the average particle diameter is preferably in a range from 0.5 nm to 500 nm, more preferably in a range from 1 nm to 400 nm and particularly preferably in a range from 1 nm to 300 nm, though it differs depending on the method of forming the organic semiconductor layer which is used in the organic semiconductor layer formation step which will be described later. This is because if the average particle diameter of the metal nanoparticles is in the range, the source and drain electrodes are made to absorb the organic semiconductor material sufficiently even if the organic semiconductor layer formation step which will be described later is a step of forming an organic semiconductor layer by using the additive method. This is also because if the average particle diameter of the metal nanoparticles exceeds the range, the retentive ability of the source and drain electrodes is deteriorated, and therefore there is the possibility that the provided organic semiconductor material bleeds out of the source and drain electrodes and is damaged due to its inferior strength and the baking temperature of the organic semiconductor layer is higher in the baking step which will be described later.

Here, the average particle diameter of the metal nanoparticles used in the metal nanoparticle coating solution is a value measured by a laser method. The average particle diameter is a general term indicating the grain size of particles and the laser method means a method in which particles are dispersed in a solvent and the scattered light obtained by applying laser rays to this dispersion medium is narrowed to calculate, for example, the average particle diameter and grain distribution. The average particle diameter is a value measured using a grain size analyzer (Microtrack UPA Model-9230, manufactured by Leeds & Northrup) as a particle diameter measuring meter using a laser method.

There is no particular limitation to the solvent used in the coating method used to apply and bake the coating solution containing the metal nanoparticles insofar as it can disperse the metal nanoparticles uniformly. In this step, the solvent is properly selected according to the metal nanoparticles to be used. Examples of the solvent may include alcohols such as methanol, ethanol, propanol, isopropyl alcohol, butanol, hexanol, heptanol, octanol, decanol, cyclohexanol and terpineol; glycols such as ethylene glycol and propylene glycol; ketones such as acetone, methyl ethyl ketone and diethyl ketone; esters such as ethyl acetate, butyl acetate and benzyl acetate; ether alcohols such as methoxy ethanol and ethoxy ethanol; ethers such as dioxane and tetrahydrofuran, acid amides such as N,N-dimethylformamide; aromatic hydrocarbons such as benzene, toluene, xylene, trimethylbenzene and dodecyl benzene; long-chain alkanes such as hexane, heptane, octane, nonane, decane, undecane, dodecane, tridecane, tetradecane, pentadecane, hexadecane, octadecane, nonadecane, eicosane and trimethylpentane; and cyclic alkanes such as cyclohexane, cycloheptane and cyclooctane. In addition, water may be used.

These solvents may be used either singly or in combinations of two or more. For example, a mineral spirit that is a mixture of long-chain alkanes may also be used.

The concentration of the metal nanoparticles contained in the metal nanoparticle coating solution obtained by dispersing the nanoparticles in a solvent is preferably in a range from 20% by mass to 90% by mass and more preferably in a range from 60% by mass to 90% by mass though it differs depending on the type of solvent. This is because the coating film can be formed at precise thickness in the coating step which will be described later if the concentration is in the range.

(Coating Step)

Next, the coating step used in the coating method in which the coating solution containing the metal nanoparticles is applied and baked will be described. This is a step of coating the gate insulation layer with the metal nanoparticle coating solution produced in the metal nanoparticle coating solution formation step.

No particular limitation is imposed on a coating method used to apply the metal nanoparticle coating solution in this step insofar as a coating film having a uniform thickness can be formed. Examples of the coating method may include coating methods such as a spin coating method, die coating method, roll coating method, bar coating method, LB method, dip coating method, spray coating method, blade coating method and casting method and printing methods such as an ink jet method, screen printing method, pad printing method, flexo printing method, micro-contact printing method, gravure printing method, offset printing method and gravure-offset printing method. Particularly, in this step, it is preferable to use a screen printing method and microcontact printing method. This is because these methods make it easy to apply the metal nanoparticle coating solution pattern-wise with high accuracy. Namely, the source and drain electrodes are easily formed pattern-wise with high accuracy.

The process may proceeds to the baking step immediately after the metal nanoparticle coating solution is applied. In this case, it is preferable to carry out a drying process to remove the solvent of the metal nanoparticle coating solution before proceeding to the baking step. This is because if the drying process is carried out, the thickness of the baked body can be restrained from being ununiform.

(Baking Step)

Next, the baking step used to apply and bake the coating solution containing metal nanoparticles will be described. In this step, a coating film of the metal nanoparticles formed on the gate insulation layer is baked to form porous source and drain electrodes.

The temperature at which the metal nanoparticles are baked is preferably in a range from 100° C. to 35° C., more preferably in a range from 100° C. to 250° C. and particularly preferably in a rage from 100° C. to 220° C. though no particular limitation is imposed on it insofar as it is possible to stick and secure metal nanoparticles at the temperature. This is because when the baking temperature is below the range, the metal nanoparticles cannot be sufficiently stuck, whereas when the baking temperature exceeds the range, there is a fear that this gives damages to other members such as the gate insulation layer on which the source and drain electrodes are to be formed, gate electrode and substrate.

Also, when the source and drain electrodes are formed by using a vapor deposition method in this step, a known method may be used as the vapor deposition method. Also, a mask vapor deposition method using a mask through which vapor deposition is performed may be used. This is because the source and drain electrodes can be directly formed pattern-wise.

The metal materials constituting the source and drain electrodes are the same as those described in the paragraph “A. Organic semiconductor device” and therefore, descriptions of these metal materials are omitted here.

4. Organic Semiconductor Layer Formation Step

Next, the organic semiconductor layer formation step used in this embodiment will be described. This step is a step of forming an organic semiconductor layer made of an organic semiconductor material only between the source and drain electrodes formed by the source/drain electrode formation step.

No particular limitation is imposed on the method of forming the organic semiconductor layer in this step insofar as it is a method enabling the formation of an organic semiconductor layer in a desired thickness only between the source and drain electrodes.

Examples of such a method may include an additive method, mask vapor deposition method and photolithographic method. Among these methods, an additive method using the source and drain electrodes as dividing walls is preferably used to form the organic semiconductor layer. This is because the organic semiconductor layer made of an organic semiconductor layer is stably formed only between the source and drain electrodes with ease.

It is also because, though in conventional methods, it is necessary to form the dividing wall by using a resin or the like to carry out the patterning of the organic semiconductor layer using the additive method, the organic semiconductor layer can be formed directly pattern-wise by using the source and drain electrodes as the dividing walls, bringing about high productivity.

Here, the additive method means a method that can provide an organic semiconductor material only between source and drain electrodes and can also provide an organic semiconductor material selectively such that an organic semiconductor layer is formed pattern-wise only between source and drain electrodes. Specific examples of the additive method include printing methods such as an ink jet method, screen printing method and flexo-printing method. In this embodiment, the organic semiconductor material is preferably formed by an inkjet method. This is because when the additive method is an ink jet method, the organic semiconductor material can be provided in a desired amount with high positional accuracy and it is therefore more easy to form the organic semiconductor layer only between the source and drain electrodes when, for example, the organic semiconductor device of the present invention is produced.

When the above additive method is used as a method of forming the organic semiconductor layer in this step, the surface of the gate insulation layer formed in the gate insulation layer formation step preferably has a liquid repellency to the coating solution for forming the organic semiconductor layer applied by the additive method. This is because the coating solution for forming the organic semiconductor layer is prevented from wetting the surface and spreading on an area other than the area between the source and drain electrodes, which ensures that the organic semiconductor layer can be formed only between the source and drain electrodes when the organic semiconductor layer is formed in this step. It is also because the semiconductor characteristics of the organic semiconductor layer to be formed on the gate insulation layer can be improved.

Here, the coating solution for forming the organic semiconductor layer and the meaning of the word “has liquid repellency to the coating solution for forming the organic semiconductor layer” are the same as those described in the paragraph “A. Organic semiconductor device” and descriptions of them will be omitted here.

No particular limitation is imposed on the level of the liquid repellency of the gate insulation layer insofar as it is on such a level just enough to prevent the coating solution for forming the organic semiconductor layer from wetting and spreading on an area other than the area between the source and drain electrodes. The level of the liquid repellency of the gate insulation layer is properly adjusted according to, for example, the composition of the coating solution for forming the organic semiconductor layer and the forms of source and drain electrodes. Here, when porous bodies are used as the source and drain electrodes, the liquid repellency is on such a level that the contact angle of the surface of the gate insulation layer with the coating solution for forming the organic semiconductor layer is preferably 40° or more, more preferably in a range from 40° to 60° and particularly preferably in a range from 40° to 45°. If the contact angle falls in the range, the coating solution for forming the organic semiconductor layer that has sunk in the source and drain electrodes can be prevented from bleeding out of the electrodes when the organic semiconductor layer is formed in the process of forming the organic semiconductor transistor of the present invention, and therefore, the organic semiconductor layer can be prevented from being formed in an area other than the area between the source and drain electrodes.

When nonporous bodies are used as the source and drain electrodes, the liquid repellency is on such a level that the contact angle of the surface of the gate insulation layer with the coating solution for forming the organic semiconductor layer is preferably 50° or more, more preferably in a range from 50° to 60° and particularly preferably in a range from 55° to 60°.

As the contact angle, values obtained by measuring according to the measuring method and measuring condition are used.

The organic semiconductor material is the same as that described in the paragraph “A. Organic semiconductor device” and descriptions thereof are omitted here.

5. Other Steps

In the manufacturing method of an organic semiconductor device in this embodiment, other steps besides the above steps may be used. No particular limitation is imposed on these other steps insofar as they respectively impart desired functions to the organic semiconductor device produced by the manufacturing method of the invention. As examples preferably used in this embodiment among these other steps, a passivation layer formation step of forming a passivation layer in such a manner as to cover the organic semiconductor layer may be given. If such a passivation layer formation step is involved in the method of this embodiment, the organic semiconductor device produced in the organic semiconductor layer formation step of this embodiment is allowed to be reduced in the deterioration of transistor characteristics.

No particular limitation is imposed on the method of forming a passivation layer in the passivation layer formation step insofar as it is a method enabling the formation of a passivation layer having a desired protective function. In particular, a method is preferably used in which a coating solution for forming the passivation layer prepared by dissolving a resin material in a solvent is used and applied to the surface of the organic semiconductor layer. Examples of such a method may include a method in which using a printing method, the coating solution for forming the passivation layer is printed pattern-wise on the organic semiconductor layer and a method in which the coating solution for forming the passivation layer is applied to the entire surface of the organic semiconductor layer to thereby form a passivation layer which is not patterned. Either of these methods may be preferably used.

The resin material is the same as that described in the paragraph “A. Organic semiconductor device” and therefore, descriptions of the resin material are omitted here.

B-2: Manufacturing Method of an Organic Semiconductor Device in a Second Embodiment

Next, a manufacturing method of an organic semiconductor device according to a second embodiment will be described. The manufacturing method of an organic semiconductor device according to this embodiment is a method of forming an organic semiconductor device provided with an organic semiconductor transistor having a top gate structure. The manufacturing method of an organic semiconductor device according to this embodiment involves a source/drain electrode formation step of using a substrate to form porous source and drain electrodes on the substrate, an organic semiconductor layer formation step of forming an organic semiconductor layer made of an organic semiconductor material only between the source and drain electrodes, a gate insulation layer formation step of forming a gate insulation layer on the organic semiconductor layer and a gate electrode formation step of forming a gate electrode on the gate insulation layer.

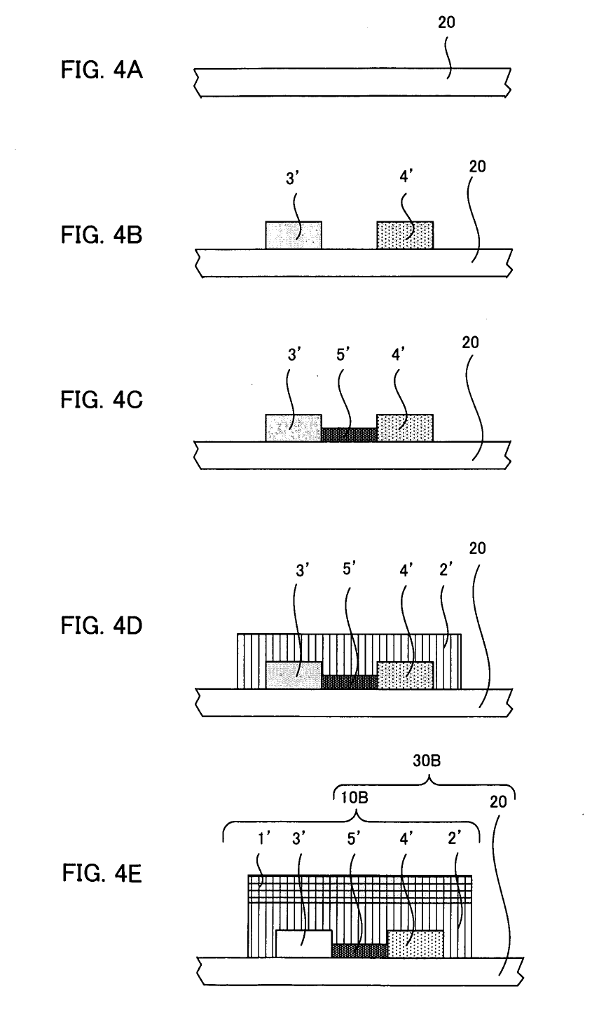

Such a manufacturing method of an organic semiconductor device of this embodiment will be described with reference to the drawings. FIG. 4 is a schematic view showing an example of the manufacturing method of an organic semiconductor device according to this embodiment. As illustrate in FIG. 4, the manufacturing method of an organic semiconductor device according to this embodiment involves a source/drain electrode formation step (FIG. 4B) of using a substrate 20 (FIG. 4A) to form porous source and drain electrodes 3′ and 4′ on the substrate 20, an organic semiconductor layer formation step (FIG. 4C) of forming an organic semiconductor layer 5′ made of an organic semiconductor material only between the source and drain electrodes 3′ and 4′, a gate insulation layer formation step (FIG. 4D) of forming a gate insulation layer 2′ on the organic semiconductor layer 5′ and a gate electrode formation step (FIG. 4E) of forming a gate electrode 1′ on the gate insulation layer 2′, to manufacture an organic semiconductor device 30B having formed thereon an organic semiconductor transistor 10B having a top gate structure on the substrate 20.

The manufacturing method of an organic semiconductor ensures that since the organic semiconductor layer made of an organic semiconductor material is formed only between the source and drain electrodes in the organic semiconductor layer formation step and therefore, an organic semiconductor device superior in on-off ratio can be manufactured.

Further, according to this embodiment, the source and drain electrodes which are porous bodies are formed in the source/drain electrode formation step. Therefore, these electrodes absorb the organic semiconductor material provided by the additive method and can stably support the organic semiconductor material between the source and drain electrodes when the organic semiconductor layer is formed in the organic semiconductor layer formation step. This enables the organic semiconductor layer to be stably supported between the source and drain electrodes and therefore the organic semiconductor layer can be formed stably with ease.

Moreover, since the organic semiconductor material can be retained stably between the electrodes as mentioned above, the source and drain electrodes are decreased in height, whereby the formation of the source and drain electrodes can be made ease. Also, the surface of the organic semiconductor device of the present invention can be easily flattened, and therefore, a passivation layer and a counter electrode can be easily formed.

The manufacturing method of an organic semiconductor device according to this embodiment comprises at least the source/drain electrode formation step, the organic semiconductor layer formation step, the gate insulation layer formation step and the gate electrode formation step, and may comprise other steps according to the need.

Each step used in this embodiment will be described in detail.

The organic semiconductor layer formation step used in this embodiment is the same as that described in the paragraph “B-1: Manufacturing method of an organic semiconductor device in the first embodiment” and therefore, descriptions of this step are omitted here.

1. Source/Drain Electrode Formation Step

The source/drain electrode formation step used in this embodiment will be described. This step is a step in which using a substrate, porous source and drain electrodes is formed on the substrate.

Here, the source/drain electrode formation step used in this embodiment is the same as that described in the paragraph “B-1: Manufacturing method of an organic semiconductor device in the first embodiment” except that the source and drain electrodes are formed on the substrate and therefore, descriptions of this step are omitted here.

2. Gate Insulation Layer Formation Step

The gate insulation layer formation step used in this embodiment is a step of forming a gate insulation layer on the organic semiconductor layer.

Here, the gate insulation layer formation step used in this embodiment is the same as that described in the paragraph “B-1: Manufacturing method of an organic semiconductor device in the first embodiment” except that the gate insulation layer is formed on the organic semiconductor layer and therefore, descriptions of this step are omitted here.

3. Gate Electrode Formation Step

The gate electrode formation step used in this embodiment is a step of forming a gate electrode on the gate insulation layer formed on the gate insulation layer formation step.

Here, the gate electrode formation step used in this embodiment is the same as that described in the paragraph “B-1: Manufacturing method of an organic semiconductor device in the first embodiment” except that the gate electrode is formed on the gate insulation layer and therefore, descriptions of this step are omitted here.

4. Other Steps

In the manufacturing method of an organic semiconductor device in this embodiment, other steps besides the above steps may be used. No particular limitation is imposed on these other steps insofar as they respectively impart desired functions to the organic semiconductor device produced by the manufacturing method of this embodiment. These other steps are the same as those described in the paragraph “B-1: Manufacturing method of an organic semiconductor device in the first embodiment” and therefore, descriptions of these steps are omitted here.

5. Others

When the above additive method is used as a method of forming the organic semiconductor layer in the organic semiconductor formation step, the surface of the substrate used in the present invention preferably has a liquid repellency to the coating solution for forming the organic semiconductor layer applied by the additive method. This is because the coating solution for forming the organic semiconductor layer is prevented from wetting the surface and spreading on an area other than the area between the source and drain electrodes, which ensures that the organic semiconductor layer can be formed only between the source and drain electrodes with ease when the organic semiconductor layer is formed in the organic semiconductor layer formation step. It is also because the semiconductor characteristics of the organic semiconductor layer to be formed on the substrate can be improved.

Here, the coating solution for forming the organic semiconductor layer and the meaning of the word “has liquid repellency to the coating solution for forming the organic semiconductor layer” are the same as those described in the paragraph “A. Organic semiconductor device” and descriptions of them will be omitted here.

No particular limitation is imposed on the level of the liquid repellency of the substrate insofar as it is on such a level just enough to prevent the coating solution for forming the organic semiconductor layer applied by the additive method from wetting and spreading on an area other than the area between the source and drain electrodes. The level of the liquid repellency of the substrate is properly adjusted according to, for example, the composition of the coating solution for forming the organic semiconductor layer and the forms of source and drain electrodes. When porous bodies are used as the source and drain electrodes, the liquid repellency is on such a level that the contact angle of the surface of the substrate with the coating solution for forming the organic semiconductor layer is preferably 40° or more, more preferably in a range from 40° to 60° and particularly preferably in a range from 40° to 45°. If the contact angle falls in the range, the coating solution for forming the organic semiconductor layer that has sunk in the source and drain electrodes can be prevented from bleeding out of the electrodes when the organic semiconductor layer is formed in the organic semiconductor layer formation step, and therefore, the organic semiconductor layer can be prevented from being formed in an area other than the area between the source and drain electrodes.

On the other hand, when nonporous bodies are used as the source and drain electrodes, the liquid repellency is on such a level that the contact angle of the surface of the gate insulation layer with the coating solution for forming the organic semiconductor layer is preferably 50° or more, more preferably in a range from 50° to 60° and particularly preferably in a range from 55° to 60°.

As the contact angle, values obtained by measuring according to the measuring method and measuring condition are used.

C. Organic Transistor Array

Next, an organic transistor array according to the present invention will be described. As mentioned above, the organic transistor array of the present invention is characterized by the use of the organic semiconductor device according to the present invention, wherein two or more of the organic semiconductor transistors are formed on the substrate. The organic transistor array of the present invention has an advantage in that it is superior in on-off ratio since the organic semiconductor device according to the present invention is used.

The organic transistor array of the present invention comprises the organic semiconductor device according to the present invention wherein plural organic semiconductor transistors are formed on a substrate. In the present invention, the structure of the organic transistor array in which two or more of the organic semiconductor transistors are formed may be properly determined according to the application of the organic transistor array of the present invention without any particular limitation.

The organic semiconductor transistor used in the organic transistor array of the present invention is the same as that described in the paragraph “A. Organic semiconductor device” and detailed descriptions of the organic transistor are therefore omitted here.

D. Display

Next, a display according to the present invention will be described. As mentioned above, the display of the present invention is characterized by the use of the organic transistor array according to the present invention. The display of the present invention has an advantage in that it has an excellent display performance.

Any display may be used as the display of the present invention without any particular limitation insofar as it has a structure in which the organic transistor array according to the present invention is used and each pixel contributing to image display is switched by each organic semiconductor transistor included in the organic transistor array. Examples of the display having such a structure may include liquid crystal display devices, electrophoresis display devices and organic EL display devices. The display devices typified by these examples are the same as those usually known in the fields concerned except that the organic transistor array is used in place of a conventional TFT array, and detailed descriptions of the display device are omitted here.

Also, the organic transistor array used in the present invention is the same as that described in the paragraph “C. Organic transistor array” and descriptions of the organic transistor array are omitted here.

The present invention is not limited to the above embodiments. These embodiments are examples and whatever has substantially the same structure and produces the same action effect as the technical spirit described in the claim of the present invention is embraced by the technical scope of the present invention.

### EXAMPLES

Next, the present invention will be described in more detail by way of examples and comparative examples.

### Example 1

In this embodiment, an organic semiconductor device provided with an organic semiconductor transistor having a top gate type structure was manufactured.

(1) Formation of a Source and Drain Electrodes

First, a silver paste (solid concentration: 90%) was applied to form patterned source and drain electrodes on a glass substrate of 150 mm×150 mm×0.7 mm by a screen printing method. After the patterning, the substrate was baked at 200° C. in an oven. Each thickness of the baked source and drain electrodes was 1.8 μm. When the formed source and drain electrodes were observed by a reflection optical microscope, the inter-electrode distance (channel length) between the source and drain electrodes was 50 μm.

(2) Formation of an Organic Semiconductor Layer

A coating solution obtained by dissolving an organic semiconductor material (polythiophene) in a solid concentration of 0.2 wt % in a trichlorobenzene solvent was applied between the source and drain electrodes by an ink jet method to thereby apply the solution by patterning only between the source and drain electrodes (channel forming portion). Thereafter, the coating layer was dried at 200° C. for 10 minutes in a N₂ atmosphere by using a hot plate to form an organic semiconductor layer. The thickness of the formed organic semiconductor layer was 0.1 μm.

(3) Formation of a Gate Insulation Layer

A cardo-type resin solution (solid concentration: 20 wt %) was applied to the substrate by spin coating. The spin coating at this time was continued at 800 rpm for 10 sec. After that, the substrate was dried at 120° C. for 2 minutes and then, subjected to pattern exposure carried out at an intensity of 350 mJ/cm². Next, the resist of the exposed part was developed and then the substrate was dried at 200° C. for 30 minutes in an oven. A gate insulation layer was formed on the organic semiconductor layer (channel forming portion) and on the source and drain electrodes. The thickness of the gate insulation layer was 1 μm.

(4) Formation of a Gate Electrode

An Ag nano-colloid solution was applied pattern-wise to the surface of the gate insulation layer by an ink jet method. Then, the coating layer was dried at 150° C. for 30 minutes by using a hot plate.

(5) Evaluation

The transistor characteristics of the organic semiconductor transistor of the manufactured organic semiconductor device were measured and as a result, this transistor was found to work as a transistor. At this time, the ON-current and OFF-current of the organic semiconductor transistor were 1×10⁻⁵ A and 2×10⁻¹³ A respectively.

### Example 2

In this embodiment, an organic semiconductor device provided with an organic semiconductor transistor having a bottom gate type structure was manufactured.

(1) Formation of a Gate Electrode

A glass substrate which had a size of 150 mm×150 mm×0.7 mm and having a film of Cr 300 nm in thickness formed thereon by a sputtering method was prepared. The substrate was coated with a photoresist (positive type) by spin coating. The spin coating at this time was continued at 1800 rpm for 10 sec. Then, the substrate was dried at 100° C. for one minute and then subjected to pattern-exposure at an intensity of 50 mJ/cm².

Next, the resist of the exposed part was developed and then the substrate was dried at 200° C. for 60 minutes in an oven. Then, Cr where no resist was present was etched to form a gate electrode.

(2) Formation of a Gate Insulation Layer

A cardo-type resin solution (solid concentration: 20 wt %) was applied to the substrate by spin coating. The spin coating at this time was continued at 800 rpm for 10 sec. After that, the substrate was dried at 120° C. for 2 minutes and then, subjected to pattern exposure carried out at an intensity of 350 mJ/cm². Next, the resist of the exposed part was developed and then the substrate was dried at 200° C. for 30 minutes in an oven. A gate insulation layer was formed on the gate electrode. The thickness of the gate insulation layer was 1 μm.

(3) Formation of a Source and Drain Electrodes

A silver paste (solid concentration: 90%) was applied to form patterned source and drain electrodes on the gate insulation layer by a screen printing method. After the patterning, the substrate was baked at 200° C. in an oven. Each thickness of the baked source and drain electrodes was 1.8 μm. When the formed source and drain electrodes were observed by a reflection optical microscope, the inter-electrode distance (channel length) between the source and drain electrodes was 50 μm.

(4) Formation of an Organic Semiconductor Layer

A coating solution obtained by dissolving an organic semiconductor material (polythiophene) in a solid concentration of 0.2 wt % in a trichlorobenzene solvent was applied between the source and drain electrodes by an ink jet method to thereby apply the solution by patterning only between the source and drain electrodes (channel forming portion). Thereafter, the coating layer was dried at 200° C. for 10 minutes in a N₂ atmosphere by using a hot plate to form an organic semiconductor layer. The thickness of the formed organic semiconductor layer was 0.1 μm.

(5) Evaluation

The transistor characteristics of the organic semiconductor transistor of the manufactured organic semiconductor device were measured and as a result, this transistor was found to work as a transistor. At this time, the ON-current and OFF-current of the organic semiconductor transistor were 8×10⁻⁶ A and 4×10⁻¹³ A respectively.

### Comparative Example 1

In this embodiment, an organic semiconductor device provided with an organic semiconductor transistor having a top gate type structure was manufactured.

(1) Formation of a Source and Drain Electrodes

First, source and drain electrodes were formed on a glass substrate of 150 mm×150 mm×0.7 mm by a vacuum deposition method. The material used in this vacuum vapor deposition method was gold and a metal mask was used to carry out patterning. Each thickness of the source and drain electrodes was 1.8 μm. When the formed source and drain electrodes were observed by a reflection optical microscope, the inter-electrode distance (channel length) between the source and drain electrodes was 50 μm.

(2) Formation of an Organic Semiconductor Layer

A coating solution obtained by dissolving an organic semiconductor material (polythiophene) in a solid concentration of 0.2 wt % in a trichlorobenzene solvent was applied pattern-wise between the source and drain electrodes (channel forming portion). However, the organic semiconductor solution bled out of the channel region. Thereafter, the coating layer was dried at 200° C. for 10 minutes in a N₂ atmosphere by using a hot plate to form an organic semiconductor layer. The thickness of the formed organic semiconductor layer was 0.1 μm and an organic semiconductor layer was formed in an area other than the channel forming portion.

(3) Formation of a Gate Insulation Layer

A cardo-type resin solution (solid concentration: 20 wt %) was applied to the substrate by spin coating. The spin coating at this time was continued at 800 rpm for 10 sec. After that, the substrate was dried at 120° C. for 2 minutes and then, subjected to pattern exposure carried out at an intensity of 350 mJ/cm². Next, the resist of the exposed part was developed and then the substrate was dried at 200° C. for 30 minutes in an oven. A gate insulation layer was formed on the organic semiconductor layer (channel forming portion) and on the source and drain electrodes. The thickness of the gate insulation layer was 1 μm.

(4) Formation of a Gate Electrode

An Ag nano-colloid solution was applied pattern-wise to the surface of the gate insulation layer by an ink jet method. Then, the coating layer was dried at 150° C. for 30 minutes by using a hot plate.

(5) Evaluation

The transistor characteristics of the organic semiconductor transistor of the manufactured organic semiconductor device were measured and as a result, this transistor was found to work as a transistor. At this time, the ON-current and OFF-current of the organic semiconductor transistor were 2×10⁻⁵ A and 3×10⁻¹⁰ A respectively, to find that the on-off ratio of this semiconductor transistor was decreased by about two digits with respect to that of Example 1.

### Comparative Example 2

In this embodiment, an organic semiconductor device provided with an organic semiconductor transistor having a bottom gate type structure was manufactured.

(1) Formation of a Gate Electrode

A glass substrate which had a size of 150 mm×150 mm×0.7 mm and having a film of Cr 300 nm in thickness formed thereon by a sputtering method was prepared. The substrate was coated with a photoresist (positive type) by spin coating. The spin coating at this time was continued at 1800 rpm for 10 sec. Then, the substrate was dried at 100° C. for one minute and then subjected to pattern-exposure at an intensity of 50 mJ/cm².

Next, the resist of the exposed part was developed and then the substrate was dried at 200° C. for 60 minutes in an oven. Then, Cr where no resist was present was etched to form a gate electrode.

(2) Formation of a Gate Insulation Layer

A cardo-type resin solution (solid concentration: 20 wt %) was applied to the substrate by spin coating. The spin coating at this time was continued at 800 rpm for 10 sec. After that, the substrate was dried at 120° C. for 2 minutes and then, subjected to pattern exposure carried out at an intensity of 350 mJ/cm². Next, the resist of the exposed part was developed and then the substrate was dried at 200° C. for 30 minutes in an oven. A gate insulation layer was formed on the gate electrode. The thickness of the gate insulation layer was 1 μm.

(3) Formation of a Source and Drain Electrodes

Source and drain electrodes were formed on the gate insulation layer by a vacuum deposition method. The material used in this vacuum vapor deposition method was gold and a metal mask was used to carry out patterning. Each thickness of the source and drain electrodes was 1.8 μm. When the formed source and drain electrodes were observed by a reflection optical microscope, the inter-electrode distance (channel length) between the source and drain electrodes was 50 μm.

(4) Formation of an Organic Semiconductor Layer

A coating solution obtained by dissolving an organic semiconductor material (polythiophene) in a solid concentration of 0.2 wt % in a trichlorobenzene solvent was applied between the source and drain electrodes (channel forming portion).

However, the organic semiconductor solution bled out of the channel region. Thereafter, the coating layer was dried at 200° C. for 10 minutes in a N₂ atmosphere by using a hot plate. The thickness of the formed organic semiconductor layer was 0.1 μm and an organic semiconductor layer was formed in an area other than the channel forming portion was to be formed.

(5) Evaluation

The transistor characteristics of the organic semiconductor transistor of the manufactured organic semiconductor device were measured and as a result, this transistor was found to work as a transistor. At this time, the ON-current and OFF-current of the organic semiconductor transistor were 4×10⁻⁵ A and 5×10⁻¹⁰ A respectively. The on-off ratio was decreased by about two-digits with respect to that of Example 2.

What is claimed is:

1. An organic semiconductor device comprising a substrate and an organic semiconductor transistor provided with a gate electrode formed on the substrate, a gate insulation layer formed on the gate electrode, source and drain electrodes which are porous bodies and are formed on the gate insulation layer and an organic semiconductor layer which is made of an organic semiconductor material and formed only between the source and drain electrodes.

2. An organic semiconductor device comprising a substrate and an organic semiconductor transistor provided with source and drain electrodes which are porous bodies and are formed on the substrate, an organic semiconductor layer which is made of an organic semiconductor material and formed only between the source and drain electrodes, a gate insulation layer formed on the organic semiconductor layer and a gate electrode formed on the gate insulation layer.

3. The organic semiconductor device according to claim 1, wherein an organic semiconductor material is contained in pores formed in the source and drain electrodes.

4. The organic semiconductor device according to claim 2, wherein an organic semiconductor material is contained in pores formed in the source and drain electrodes.

5. The organic semiconductor device according to claim 1, wherein the organic semiconductor layer is formed by an additive method using the source and drain electrodes as dividing walls.

6. The organic semiconductor device according to claim 2, wherein the organic semiconductor layer is formed by an additive method using the source and drain electrodes as dividing walls.

7. The organic semiconductor device according to claim 5, wherein the additive method is an ink jet method.

8. The organic semiconductor device according to claim 6, wherein the additive method is an ink jet method.

9. The organic semiconductor device according to claim 1, wherein the organic semiconductor layer is formed by an additive method using the source and drain electrodes as dividing walls and the surface of the gate insulation layer has liquid repellency to a coating solution for forming the organic semiconductor layer to be used in the additive method.

10. The organic semiconductor device according to claim 2, wherein the organic semiconductor layer is formed by an additive method using the source and drain electrodes as dividing walls and the surface of the substrate has liquid repellency to a coating solution for forming the organic semiconductor layer to be used in the additive method.

11. The organic semiconductor device according to claim 9, wherein the liquid repellency is on such a level that the contact angle of the surface of the gate insulation layer with the coating solution for forming the organic semiconductor layer is 40° or more.

12. The organic semiconductor device according to claim 10, wherein the liquid repellency is on such a level that the contact angle of the surface of the gate insulation layer with the coating solution for forming the organic semiconductor layer is 40° or more.

13. A manufacturing method of an organic semiconductor device, the method comprising:
a gate electrode formation step of using a substrate to form a gate electrode on the substrate;
a gate insulation formation step of forming a gate insulation layer on the gate electrode;
a source/drain electrode formation step of forming source and drain electrodes which are porous bodies and are formed on the gate insulation layer; and
an organic semiconductor layer formation step of forming an organic semiconductor layer made of an organic semiconductor material only between the source and drain electrodes.

14. A manufacturing method of an organic semiconductor device, the method comprising:
a source/drain electrode formation step of using a substrate to form source and drain electrodes which are porous bodies and are formed on the substrate;
an organic semiconductor layer formation step of forming an organic semiconductor layer made of an organic semiconductor material only between the source and drain electrodes;
a gate insulation layer formation step of forming a gate insulation layer on the organic semiconductor layer; and
a gate electrode formation step of forming a gate electrode on the gate insulation layer.

15. The manufacturing method of an organic semiconductor device according to claim 13, wherein the organic semiconductor layer formation step is a step of forming the organic semiconductor layer made of the organic semiconductor material by an additive method using the source and drain electrodes as dividing walls.

16. The manufacturing method of an organic semiconductor device according to claim 14, wherein the organic semiconductor layer formation step is a step of forming the organic semiconductor layer made of the organic semiconductor material by an additive method using the source and drain electrodes as dividing walls.

17. The manufacturing method of an organic semiconductor device according to claim 15, wherein the additive method is an ink jet method.

18. The manufacturing method of an organic semiconductor device according to claim 16, wherein the additive method is an ink jet method.

19. The manufacturing method of an organic semiconductor device according to claim 13, wherein the source/drain electrode formation step is a step of forming source and drain electrodes by a coating method in which a coating solution containing metal nanoparticles is applied and baked.

20. The manufacturing method of an organic semiconductor device according to claim 14, wherein the source/drain electrode formation step is a step of forming source and drain electrodes by a coating method in which a coating solution containing metal nanoparticles is applied and baked.

21. The manufacturing method of an organic semiconductor device according to claim 13, wherein the organic semiconductor layer formation step is a step of forming an organic semiconductor layer by an additive method using the source and drain electrodes as dividing walls and the surface of the gate insulation layer formed in the gate insulation layer formation step has liquid repellency to a coating solution for forming the organic semiconductor layer to be used in the additive method.

22. The manufacturing method of an organic semiconductor device according to claim 14, wherein the organic semiconductor layer formation step is a step of forming an organic semiconductor layer by an additive method using the source and drain electrodes as dividing walls and the surface of the substrate has liquid repellency to a coating solution for forming the organic semiconductor layer to be used in the additive method.

23. The manufacturing method of an organic semiconductor device according to claim 21, wherein the source/drain electrode formation step is a step of forming source and drain electrodes by a coating method in which a coating solution containing metal nanoparticles is applied and baked and the liquid repellency is on such a level that the contact angle of the surface of the gate insulation layer with the coating solution for forming the organic semiconductor layer is 40° or more.

24. The manufacturing method of an organic semiconductor device according to claim 22, wherein the source/drain electrode formation step is a step of forming source and drain electrodes by a coating method in which a coating solution containing metal nanoparticles is applied and baked and the liquid repellency is on such a level that the contact angle of the surface of the gate insulation layer with the coating solution for forming the organic semiconductor layer is 40° or more.

25. An organic transistor array using the organic semiconductor device as claimed in claim 1, wherein two or more of the organic semiconductor transistors are formed on the substrate.

26. An organic transistor array using the organic semiconductor device as claimed in claim 2, wherein two or more of the organic semiconductor transistors are formed on the substrate.

27. A display using the organic transistor array as claimed in claim 25.

28. A display using the organic transistor array as claimed in claim 26.
